(19) United States
(12) Patent Application Publication
(10) Pub. No.: US 2011/0098841 A1
(43) Pub. Date: Apr. 28, 2011

(54) GAS SUPPLY DEVICE, PROCESSING APPARATUS, PROCESSING METHOD, AND STORAGE MEDIUM

(75) Inventor: Einosuke Tsuda, Yamanashi-Ken (JP)

(73) Assignee: TOKYO ELECTRON LIMITED, Tokyo-To (JP)

(21) Appl. No.: 12/934,473

(22) PCT Filed: Mar. 23, 2009
(86) PCT No.: PCT/JP2009/055658

§ 371 Date: Dec. 13, 2010

(30) Foreign Application Priority Data
Mar. 27, 2008 (JP) 2008-084217

(51) Int. Cl. C23C 16/455; C23C 16/458; C23F 1/08; C23F 1/00; F17D 1/04; G06F 17/00

(52) U.S. Cl. 700/117; 118/728; 156/345.33; 427/255.23; 427/255.28; 216/58; 216/37; 137/255

(57) ABSTRACT

A gas supply device 3 includes a device body 31 forming a substantially conical gas-conducting space 32 for conducting gases therethrough from a diametrally reduced end 32a of the space 32 to a diametrally enlarged end 32b thereof, gas introduction ports 61a to 63a, 61b to 63b, and 64, each provided near the diametrally reduced end 32a of the gas-conducting space 32 in the device body 31 to introduce the gases into the gas-conducting space 32, and a plurality of partitioning members 41 to 46 provided in the gas-conducting space 32 of the device body 31 to partition the gas-conducting space 32 concentrically. The partitioning members 42 to 46 arranged adjacently to each other at a radially outer side of the gas-conducting space 32 are greater than the adjacently arranged partitioning members 41 to 45 at a radially inner side in dimensionally diverging rate per partitioning member. Thus, internal gas flow channels of the gas supply device have high gas conductance and enhanced gas replaceability, compared with those of the conventional gas showerhead.

### FIELD OF THE INVENTION

The present invention relates to a gas supply device for supplying process gases to a substrate, a processing apparatus including the gas supply device, a processing method using the gas supply device, and a storage medium.

### BACKGROUND OF THE INVENTION

A gas showerhead is used as a device for supplying gases to an apparatus that conducts chemical vapor deposition (CVD), etching, and the like. The gas showerhead has a flattened columnar shape. The showerhead, when supplied with gases through gas introduction ports provided at its upper section, will supply the gases in shower form from a large number of orifices in a lower surface of the showerhead by diffusing the gases from an internal diffusion space. Two major known types of gas showerheads are available to supply multiple kinds of process gases. One type is so-called “premixing”, which mixes multiple kinds of process gases midway in one gas flow channel line before supplying the gases, and the other type is “post-mixing”, which supplies multiple kinds of gases through independent lines.

So-called atomic layer deposition (ALD), a method of forming films, is also known. In ALD, multiple kinds of process gases are supplied separately in two steps (e.g., supplying a first process gas in a first step and a second process gas in a second step, and alternating this procedure between the two steps) and after this, reaction products of the process gases are sequentially stacked to form a film.

Because of their complexity and narrowness, internal gas flow channels of the showerhead have low gas conductance and are poor in gas replaceability. Accordingly, ALD employs the post-mixing type of showerhead to prevent the process gases supplied with a time difference, from generating reaction products in the showerhead by getting mixed with each other therein.

FIG. 17 shows an exemplary longitudinal section of the gas showerhead. The gas showerhead 1 in FIG. 17 is of a stacked structure with a shower plate 11, a device body 12, a base member 13, and other members bonded to one another, each of these members being flattened circular. A first gas that has been supplied from a first gas supply line 14A becomes diffused in a gas diffusion space 15A formed between the device body 12 and the base member 13, and is supplied to a first discharge port 16A. A second gas that has been supplied from a second gas supply line 14B becomes diffused in a gas diffusion space 15B formed between the device body 12 and the shower plate 11, and is supplied to a second discharge port 168. In this way, the first gas and the second gas are each discharged from the discharge ports 16A and 16B independently to avoid intermixing in the gas showerhead 1.

In the ALD process, to change the kinds of process gases to be supplied from the gas showerhead 1, the process gas left in a processing atmosphere for the film deposition needs to be completely eliminated by supplying a purging gas before the next process gas can be supplied. For improved throughput, the step of supplying the purging gas during the process gas change should be completed within a time as short as possible.

In the gas showerhead 1, however, since the conductance of the gases in the flow channels is low as discussed above, limiting the purging gas supply time too much could cause the immediately previous (earlier supplied) process gas to remain in corners or other sections of the gas diffusion space 15A or 15B.

If the next (subsequent) process gas is supplied with the previous process gas remaining in the showerhead, this residual gas will flow out into the processing space for the wafer. As a result, the previous process gas and the next one will react upon each other on the surface of the showerhead 1, causing deposits to stick to the surface. This may contaminate the wafer W with particles or cause reaction products to directly stick as particles to the wafer surface, resulting in films failing to deposit on the wafer. For these reasons, the purging time cannot be made too short and throughput is difficult to improve.

In addition, during ALD, CVD, or plasma etching, the wafer W is heated to a predetermined temperature and thus the processing space surrounding the wafer is also heated. It may be preferable, therefore, that ceramics, a mixture of silicon carbide (SiC) and aluminum, or other materials of low heat expansion rates be used to construct the gas showerhead 1. However, the gas showerhead has a complex, stacked structure, as described above, and fine-structured flow channels need to be formed. While the shower plate 11, in particular, requires perforation with a large number of orifices, it is difficult to provide the above materials with such a fine-structuring process. These situations have presented the problems that the showerhead 11 is difficult to manufacture and that the types of materials useable for the manufacture are limited.

JP-A-7-22323 describes a vapor deposition apparatus adapted to supply various gases from the respective flow channels that increase in width as they go downward. However, JP-A-7-22323 does not describe solutions to the above-discussed problems occurring when the gases are replaced with each other.

### SUMMARY OF THE INVENTION

The present invention has been made with the above taken into account, and is intended to provide a gas supply device capable to replace process gases in its internal gas flow channels rapidly when it supplies the gases to a substrate to be subjected to processing. The invention is also intended to provide a processing apparatus including the gas supply device, a processing method using the gas supply device, and a storage medium.

A gas supply device according to a first aspect of the present invention is disposed oppositely to a substrate in a process chamber and constructed to supply process gases to the substrate so as to process the substrate. The device includes a device body having a gas-conducting space therein, the gas-conducting space having a diametrally reduced end and a diametrally enlarged end and being formed into a substantially conical shape to thereby conduct the gases from the diametrally reduced end through the gas-conducting space to the diametrally enlarged end. The device also includes gas introduction ports provided near the diametrally reduced end of the gas-conducting space in the device body to introduce the gases into the gas-conducting space, and a plurality of partitioning members provided in the gas-conducting space of the device body to partition the gas-conducting space concentrically; wherein the partitioning members arranged adjacently to each other at a radially outer side of the gas-conducting space are greater than those of a radially inner side in dimensionally diverging rate per partitioning member.

In the gas supply device according to the first aspect of the present invention, a gas introduction route extending in an axial direction of the gas-conducting space is formed at an upstream side of the gas-conducting space in the device body, with the gas introduction ports provided at an upstream side of the gas introduction route.

In the gas supply device according to the first aspect of the present invention, the partitioning members are each supported by support members that extend from an inner circumferential surface of the device body, towards a radially inward side of the gas-conducting space.

In the gas supply device according to the first aspect of the present invention, the partitioning members partition the gas-conducting space into a plurality of flow channels, each of which is formed so that radially inner flow channels have lower gas conductance than radially outer ones.

The gas supply device according to the first aspect of the present invention includes an airflow control member disposed in a radially central region of the gas-conducting space to prevent the gases from flowing into the central region.

The gas supply device according to the first aspect of the present invention comprises a divider member provided in the gas introduction route to divide the gas introduction route into a radially inner region thereof and a radially outer region thereof, the divider member including a plurality of orifices to diffuse the gases supplied to the inner region towards the outer region; wherein the gases from the gas introduction ports are supplied to the inner region.

In the gas supply device according to the first aspect of the present invention, the divider member is connected to upstream ends of the partitioning members.

A gas supply device according to a second aspect of the present invention is disposed oppositely to a substrate in a process chamber and constructed to supply gases to the substrate so as to process the substrate. The device includes a device body having a gas-conducting space therein, the gas-conducting space having a diametrally reduced end and a diametrally enlarged end and being formed into a substantially conical shape to thereby conduct the gases from the diametrally reduced end through the gas-conducting space to the diametrally enlarged end. The device also includes gas introduction ports provided near the diametrally reduced end of the gas-conducting space in the device body to introduce the gases into the gas-conducting space, and a plurality of partitioning members provided in the gas-conducting space of the device body to partition the gas-conducting space in a circumferential direction thereof.

In the gas supply device according to the second aspect of the present invention, a gas introduction route extending in an axial direction of the gas-conducting space is formed at an upstream side of the gas-conducting space in the device body, with the gas introduction ports provided at an upstream side of the gas introduction route.

In the gas supply device according to the second aspect of the present invention, the plurality of partitioning members are each constructed so that the gases supplied from the diametrally enlarged end of the gas-conducting space flow while forming a vortex flow that rotates in the circumferential direction of the device body.

In the gas supply device according to the second aspect of the present invention, the partitioning members extend radially from the central region of the gas-conducting space.

In the gas supply device according to the second aspect of the present invention, the partitioning members are provided to range from the diametrally reduced end to the diametrally enlarged end, in the gas-conducting space.

A gas supply device according to a third aspect of the present invention is disposed oppositely to a substrate in a process chamber and constructed to supply gases to the substrate so as to process the substrate. The device includes a device body with a gas-conducting space for conducting the gases therethrough. The device also includes gas introduction ports provided near an upstream end of the gas-conducting space in the device body to introduce the gases into the gas-conducting space, and a plate-like member provided near a downstream end of the gas-conducting space in the device body and having a plurality of concentrically opened slits for supplying the gases to the substrate through the gas-conducting space.

In the gas supply device according to the third aspect of the present invention, a gas introduction route extending in an axial direction of the gas-conducting space is formed at an upstream side of the gas-conducting space in the device body, with the gas introduction ports provided at an upstream side of the gas introduction route.

In the gas supply device according to the third aspect of the present invention, the slits are formed to increase in interslit width as they go radially from a central portion of the plate-like member, towards an outer edge of the member.

The gas supply device according to the third aspect of the present invention further includes temperature control means in the device body.

A processing apparatus according to a fourth aspect of the present invention includes a mounting table for mounting a substrate thereon, a process chamber with the mounting table provided therein, a gas supply device provided oppositely to the mounting table, for supplying plural kinds of process gases to the process chamber interior to process the substrate, and means for evacuating the process chamber interior. The gas supply device includes a device body having a gas-conducting space therein, the gas-conducting space having a diametrally reduced end and a diametrally enlarged end and being formed into a substantially conical shape to thereby conduct the gases from the diametrally reduced end through the gas-conducting space to the diametrally enlarged end. The gas supply device also includes gas introduction ports provided near the diametrally reduced end of the gas-conducting space in the device body to introduce the gases into the gas-conducting space, and a plurality of partitioning members provided in the gas-conducting space of the device body to partition the gas-conducting space concentrically; wherein the partitioning members arranged adjacently to each other at a radially outer side of the gas-conducting space are greater than those of a radially inner side in dimensionally diverging rate per partitioning member.

The processing apparatus according to the fourth aspect of the present invention further includes a plurality of process gas flow channels connected to the gas introduction ports of the gas supply device, the process gas flow channels each being formed to supply any one of the plural kinds of process gases. Furthermore, the apparatus includes a purging gas flow channel connected to any one of the gas introduction ports of the gas supply device, the purging gas flow channel being formed to supply an inert gas for purging. Moreover, the apparatus includes a supply gas control device that controls a supply state of the gases in the process gas flow channels and in the purging gas flow channel, and a control unit that controls the supply gas control device to conduct the step of, in addition to supplying the plural kinds of process gases in order and cyclically, supplying the inert gas between the step of supplying one of the plural kinds of process gases and the step of supplying the other kind of process gas; wherein layers that include reaction products of the plural kinds of process gases are sequentially stacked on the surface of the substrate to form a thin film thereon.

A processing method according to a fifth aspect of the present invention includes the steps of mounting a substrate on a mounting table provided in a process chamber, supplying process gases for processing the substrate, from a gas supply device opposed to the mounting table, to the process chamber interior, and evacuating the process chamber interior. The gas supply device includes a device body having a gas-conducting space therein, the gas-conducting space having a diametrally reduced end and a diametrally enlarged end and being formed into a substantially conical shape to thereby conduct the gases from the diametrally reduced end through the gas-conducting space to the diametrally enlarged end. The gas supply device also includes gas introduction ports provided near the diametrally reduced end of the gas-conducting space in the device body to introduce the gases into the gas-conducting space, and a plurality of partitioning members provided in the gas-conducting space of the device body to partition the gas-conducting space concentrically; wherein the partitioning members arranged adjacently to each other at a radially outer side of the gas-conducting space are greater than those of a radially inner side in dimensionally diverging rate per partitioning member.

In the processing method according to the fifth aspect of the present invention, the step of supplying the process gases includes the substep of, in addition to supplying the plural kinds of process gases in order and cyclically, supplying an inert gas between the step of supplying one of the plural kinds of process gases and the step of supplying the other kind of process gas; wherein layers that include reaction products of the plural kinds of process gases are sequentially stacked on the surface of the substrate to form a thin film thereon.

According to a sixth aspect of the present invention, a storage medium has stored therein a computer program that operates on a computer, the storage medium being used in a processing method, the processing method comprising the steps of: mounting a substrate on a mounting table provided in a process chamber, supplying process gases for processing the substrate, from a gas supply device opposed to the mounting table, to the process chamber interior, and evacuating the process chamber interior. The gas supply device includes a device body having a gas-conducting space therein, the gas-conducting space having a diametrally reduced end and a diametrally enlarged end and being formed into a substantially conical shape to thereby conduct the gases from the diametrally reduced end through the gas-conducting space to the diametrally enlarged end. The gas supply device also includes gas introduction ports provided near the diametrally reduced end of the gas-conducting space in the device body to introduce the gases into the gas-conducting space, and a plurality of partitioning members provided in the gas-conducting space of the device body to partition the gas-conducting space concentrically; wherein the partitioning members arranged adjacently to each other at a radially outer side of the gas-conducting space are greater than those of a radially inner side in dimensionally diverging rate per partitioning member.

According to the present invention, conductance of the gases in the flow channels to the substrate is increased and the gases are rapidly replaced in the gas-conducting space. In addition, the gas supply device of the invention is easy to manufacture, since the device, unlike the one used in related conventional technology, requires no precise, complex working of the members of various stages. This, in turn, yields a further advantage of great flexibility in selection of the kinds of useable materials. Moreover, applying the gas supply device to ALD or other schemes in which a film is deposited by supplying plural kinds of process gases cyclically in order leads to more rapid replacement of the gases within the gas supply device by means of a purging gas, thus contributing to the improvement of throughput.

### BRIEF DESCRIPTION OF THE DRAWINGS

FIG. 1 is a longitudinal sectional view of a film deposition apparatus including a gas supply unit of a gas supply device according to a first embodiment of the present invention;

FIG. 2 is a longitudinal sectional view of the gas supply unit;

FIG. 3 is a transverse sectional view of the gas supply unit;

FIG. 4 is a longitudinal perspective view of the gas supply unit;

FIG. 5 is a perspective bottom view of the gas supply unit;

FIG. 6 is a diagram representing a vortex flow created in a gas-conducting space of the gas supply unit;

FIGS. 7(a) to 7(d) are process diagrams of ALD with the deposition apparatus;

FIGS. 8(a) to 8(c) are explanatory diagrams showing a first modification of the gas supply unit;

FIGS. 9(a) and 9(b) are explanatory diagrams showing a second modification of the gas supply unit;

FIGS. 10(a) and 10(b) are explanatory diagrams showing a third modification of the gas supply unit;

FIGS. 11(a) to 11(c) are explanatory diagrams showing a second embodiment of the gas supply unit;

FIG. 12 is a longitudinal perspective view showing a third embodiment of the gas supply unit;

FIGS. 13(a) and 13(b) are a bottom view, and a perspective bottom view, respectively, of the gas supply unit in the third embodiment;

FIG. 14 is a longitudinal perspective view showing a peripheral structure of gas introduction ports of the gas supply unit;

FIGS. 15(a) and 15(b) are gas concentration distribution diagrams of a processing space simulated during evaluation testing;

FIG. 16 is a perspective view of a gas flow channel simulation model used during evaluation testing; and

FIG. 17 is a longitudinal sectional view of a conventional gas showerhead.

### DESCRIPTION OF THE PREFERRED EMBODIMENTS

### First Embodiment

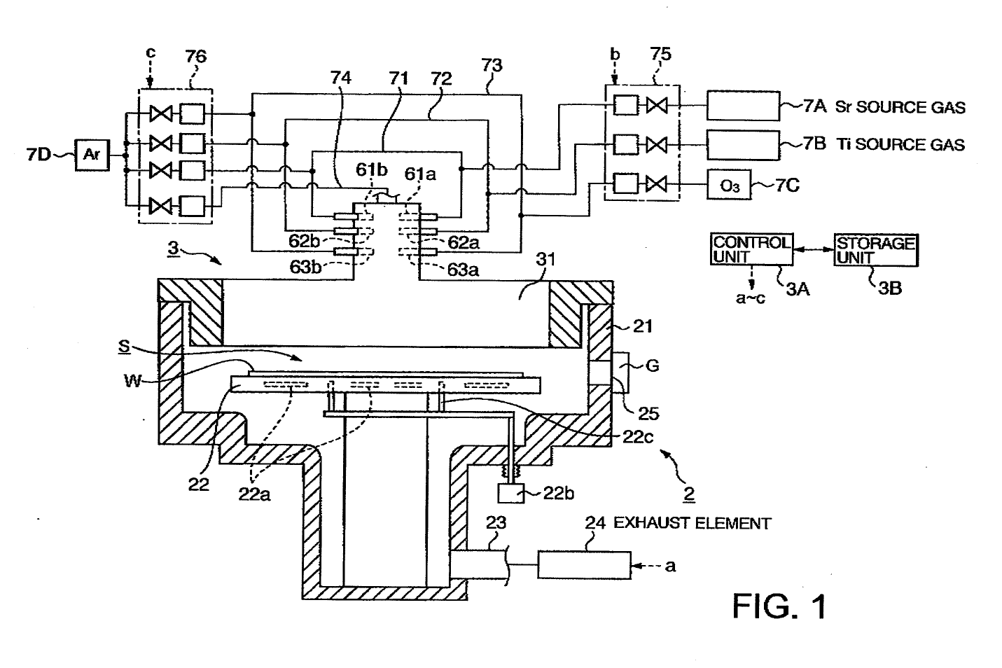

A total apparatus configuration of a film deposition apparatus 2, a first embodiment of the present invention, will be first described referring to FIG. 1.

The film deposition apparatus 2 according to the present embodiment has a function that uses an ALD process to deposit a thin film of strontium titanate (SrTiO₃, hereinafter abbreviated to STO) as a highly dielectric material, on the surface of a semiconductor wafer (hereinafter referred to the wafer) W as a substrate. The deposition is accomplished by reacting a strontium-containing source gas (hereinafter referred to as the Sr source gas) as a first process gas, and a titanium-containing source gas (hereinafter referred to as the Ti source gas) as a second process gas, upon an ozone (O₃) gas that is an oxidation gas as a third process gas.

The deposition apparatus 2 includes a process chamber 21. A mounting table 22 for mounting the wafer W horizontally thereon is provided in the process chamber 21. The mounting table 22 contains heaters 22a that serves as temperature controllers for the wafer W. The mounting table 22 also has three lifting pins 22c perpendicularly movable by a lifter 22b, only two of the three pins being shown for convenience sake. The wafer W is transferred between the mounting table 22 and a wafer transport mechanism (not shown) that is provided externally to the deposition apparatus 2 via the lifting pins 22c.

The process chamber 21 has an exhaust line 23 connected at one end thereof to a bottom section of the chamber. An exhaust element 24 including a vacuum pump and the like is connected to the other end of the exhaust line 23. The exhaust element 24 includes a pressure regulator not shown. This allows the exhaust element 24 to maintain an internal pressure of the process chamber 21 at a predetermined level in accordance with a control signal from a control unit 3A (described later herein). In addition, a carrying-in port 25 that is opened and closed by a gate valve G is formed in a sidewall of the process chamber 21. Reference symbol S in FIG. 1 denotes a processing space surrounding the wafer W mounted on the mounting table 22.

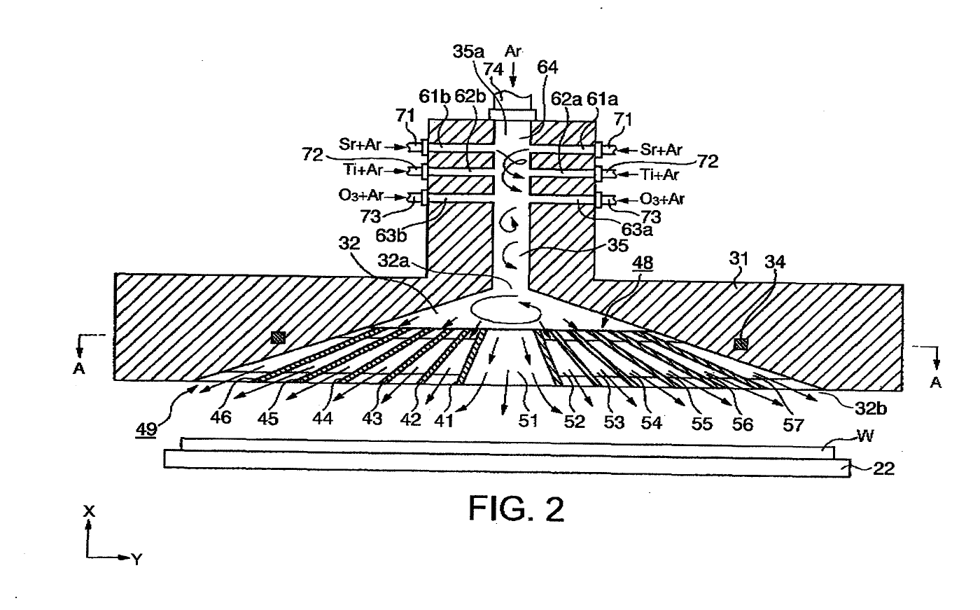

A gas supply unit 3 that forms part of the gas supply device of the present invention is provided on an upper section of the process chamber 21 so as to face the wafer W mounted on the mounting table 22. The gas supply unit 3 is described below referring to FIGS. 2 to 4 that show the unit in longitudinal or transverse sectional side view or in perspective view.

The gas supply unit 3 has a device body 31 formed to have an inversed T-shape when viewed from a lateral direction. That is to say, the device body 31 is formed at a lower section thereof to have a flattened, large-diameter, cylindrical shape, and at an upper section thereof to have a small-diameter cylindrical shape. A gas-conducting space 32 heading from an upward end, towards a lower end, is formed inside the device body 31. The gas-conducting space 32 is formed into a nearly conical shape extending from the upward end of the gas-conducting space to the lower end thereof.

Partition members 41 to 46 ranging from the side of a diametrally reduced end 32a of the gas-conducting space 32 to the side of a diametrally enlarged end 32b thereof are arranged in the gas-conducting space 32 of the device body 31. The partitioning members 41 to 46 are each formed into a tubular shape progressively enlarged in diameter as the member goes downward from the diametrally reduced end 32a, towards the diametrally enlarged end 32b. The partitioning members 41 to 46 have diameters different from one another, and are arranged radially from the inside of the gas-conducting space 32 to the outside thereof, in numerically ascending order of the partitioning members. In addition, the partitioning members 41 to 46 partition the gas-conducting space 32 concentrically to form gas flow channels 51 to 57, respectively. The partitioning members 41 to 46 are arranged adjacently to each other so that a downstream progressive enlarging rate per partitioning member, that is, magnitude of an angle relative to an axial direction of the gas-conducting space 32, is greater at radially outer positions in the gas-conducting space than at radially inner positions. More specifically, the partitioning members 46, 45, 44, 43, 42, and 41 are arranged to be greater in downstream progressive enlarging rate, in that order.

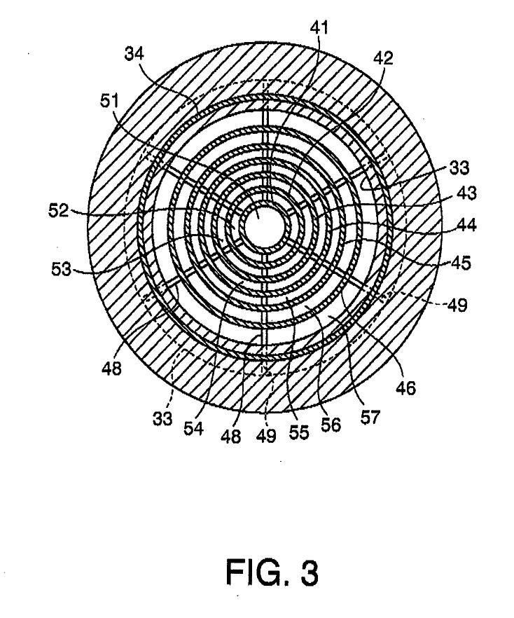

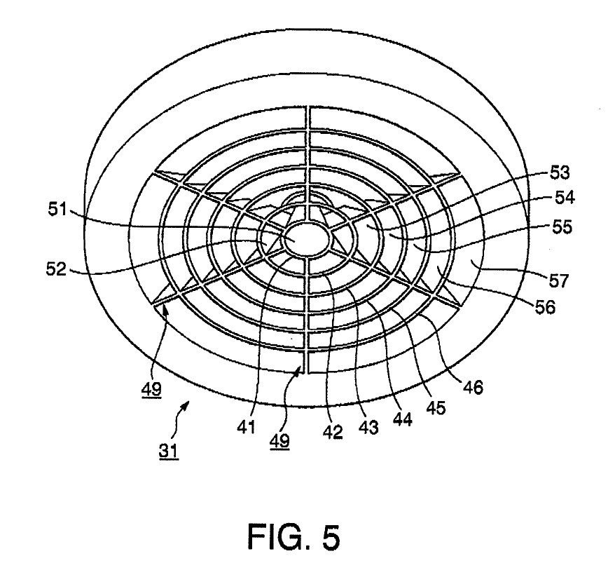

FIG. 3 is a sectional view taken along line A-A in FIG. 2, and FIG. 5 is a perspective view taken when the device body 31 is viewed from its downward side. As shown in these figures, the partitioning members 41 to 46 are each supported at an upper end and lower end thereof by a plurality of supports 48 and 49. The supports 48 and 49 each extend in the radial direction of the gas-conducting space 32, from an inner circumferential surface 33 of the device body 31 towards the partitioning member 41, respectively. In other words, the supports 48 and 49 each extend radially from the innermost partitioning member 41, towards the inner circumferential surface 33 of the device body 31. In addition to supporting the partitioning members 41 to 46, the supports 48 and 49 serve to transmit heat from a temperature controller provided in the device body 31, such as a heater 34, to the partitioning members 41 to 46, and thus to avoid film deposition on the surfaces of the partitioning members 41 to 46 by preventing the process gases from being cooled thereon.

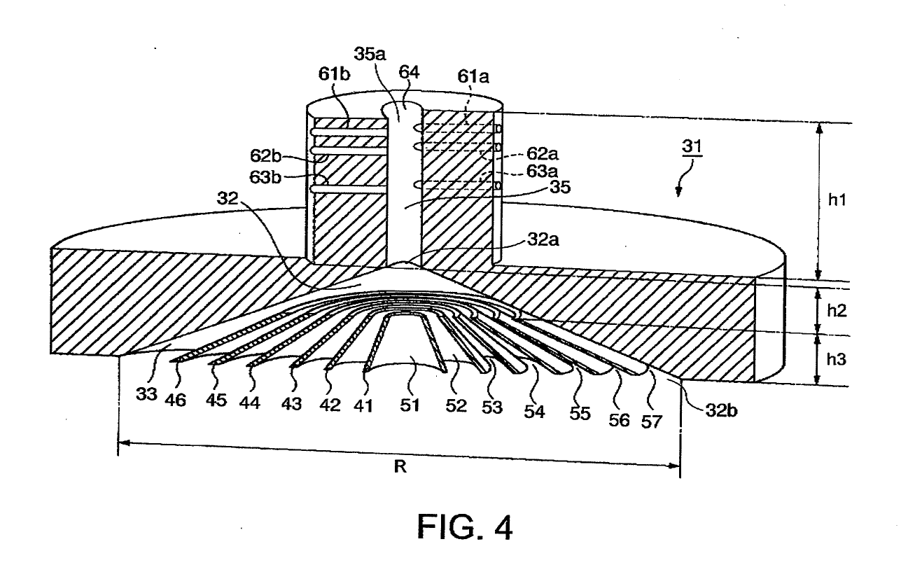

In addition, as shown in FIG. 3, the heater 34 is provided in the device body 31 so as, for example, to surround the gas-conducting space 32 and the partitioning members 41 to 46. In FIG. 4, the supports 48 and 49 are omitted for the sake of convenience in illustration.

As shown in FIGS. 2 and 4, at an upstream side of the gas-conducting space 32 in the device body 31, a gas introduction route 35 extending in the axial direction of the gas-conducting space 32 is formed. Gas introduction ports 61a, 61b, 62a, 62b, 63a, and 63b for supplying the gases to the gas-conducting space 32 via the gas introduction route 35 are provided in a sidewall of the gas introduction route 35. The gas introduction ports 61a, 62a, and 63a are formed in this order in the side or perspective views of FIGS. 2 and 4. Similarly, the gas introduction ports 61b, 62b, and 63b are formed in this order in the side or perspective views of FIGS. 2 and 4.

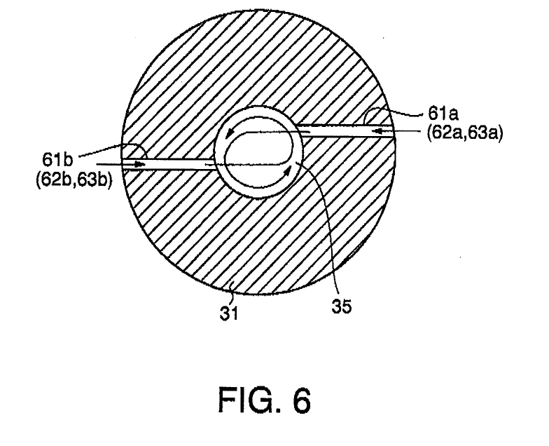

As shown in FIG. 4, for example, the gas introduction ports 61a to 63a and 61b to 63b each have an orifice that is circular in perpendicular section and opened in a lateral direction of the device body 31. In addition, in FIG. 2, if a direction orthogonal to both X- and Y-axes (i.e., perpendicular to the paper) is defined as a longitudinal direction, the gas introduction ports 61a to 63a and 61b to 63b are arranged for a longitudinal shift in position from each other. As shown in FIG. 6, the gases that have been supplied from the gas introduction ports 61a to 63a and 61b to 63b extend downward while each forming a vortex flow rotating circumferentially in the gas introduction route 35.

Referring also to FIG. 4, the gas introduction route 35 in the device body 31 has a height h1 of 80 mm, for example, and the gas-conducting space 32 has a height h2 of 20 mm, for example, from the diametrally reduced end 32a to an upper end of each partitioning member 41 to 46. Height h3 from the upper end of each partitioning member 41 to 46 to a lower end thereof is 30 mm, for example. Diameter R of the gas-conducting space 32, at the diametrally enlarged end 32b thereof, is 300 mm, for example.

Gas supply lines 71 to 73 for supplying various gases are connected to the gas introduction ports 61a to 63a and 61b to 63b, as shown in FIGS. 1 and 2. More specifically, the gas introduction ports 61a and 61b are connected to the strontium (Sr) source gas supply line 71, the gas introduction ports 62a and 62b, to the titanium (Ti) source gas supply line 72, and the gas introduction ports 63a and 63b, to the ozone (O₃) gas supply line 73.

The Sr source gas supply line 71 is connected to a strontium (Sr) supply source 7A, in which is stored a liquid Sr source material such as strontium bis-tetramethylheptanedionato known as Sr(THD)₂, or bis-pentamethylcyclopentadienyl strontium known as Sr(Me₅Cp)₂. The Sr source material is pushed out and then vaporized by a vaporizer not shown, with the result that the Sr source gas is supplied to the Sr source gas supply line 71.

The Ti source gas supply line 72 is connected to a titanium (Ti) supply source 7B, in which is stored a Ti source material such as titanium bis-isopropoxide-bis-tetramethylheptanedionato) known as Ti(OiPr)₂(THD)₂, or titanium tetra-isopropoxide) known as Ti(OiPr). As with the Sr source material, the Ti source gas that has been formed by vaporizing with a vaporizer not shown is supplied to the Ti source gas supply line 72.

The ozone gas supply line 73 is connected to an ozone gas supply source 7C, for example. Additionally, the Sr source gas supply line 71, the Ti source gas supply line 72, and the ozone gas supply line 73 are each branched midway and connected to an argon (Ar) gas supply source 7D, so that the Ar gas, together with the respective process gases, can be supplied to the gas introduction ports 61a to 63a and 61b to 63b.

Furthermore, a gas introduction port 64 opened in an upper section of the device body 31 is formed at an upper end 35a of the gas introduction route 35. A gas supply line 74 is connected at one end thereof to the gas introduction port 64. The gas supply line 74 is connected at the other end thereof to the Ar gas supply source 7D. The gas supply line 74 supplies the Ar gas to the gas-conducting space 32 to accelerate the flow of each gas therein. Thus, in the film deposition process described later herein, the film deposition using the process gases supplied from the gas introduction ports 61a to 63a and 61b to 63b improves in efficiency, and in a purging process, the time required for purging is reduced. The Ar gas from the gas supply line 74 is called a counter gas.

On the gas supply lines 71 to 74, flow control device groups 75 and 76 each including valves, flow meters, and the like, are provided to control supply timing and supply rates of each gas in accordance with instructions from the control unit 3A described below.

The film deposition apparatus 2 has the control unit 3A including a computer, for example, and the control unit 3A also includes a program. This program contains instructions (steps) to send control signals from the control unit 3A to various sections of the deposition apparatus 2 and accelerate wafer processing. The program (Including a program relating to process parameter entry operations and display) is stored into a storage unit 3B including a computer storage medium such as a flexible disk, compact disk, hard disk, or magneto-optic (MO) disk, and installed in the control unit 3A.

The process of forming a thin film of strontium titanate (SrTiO₃, hereinafter referred to as STO) on the wafer W with the deposition apparatus 2 is described below. First, the wafer W is carried into the process chamber 21 via the carrying-in port 25 by an external wafer transport mechanism. Next, the wafer W is mounted on the mounting table 22 via the lifting pins 22c. After this, the wafer W is heated to a predetermined temperature and the process chamber 21 is evacuated to a predetermined vacuum pressure.

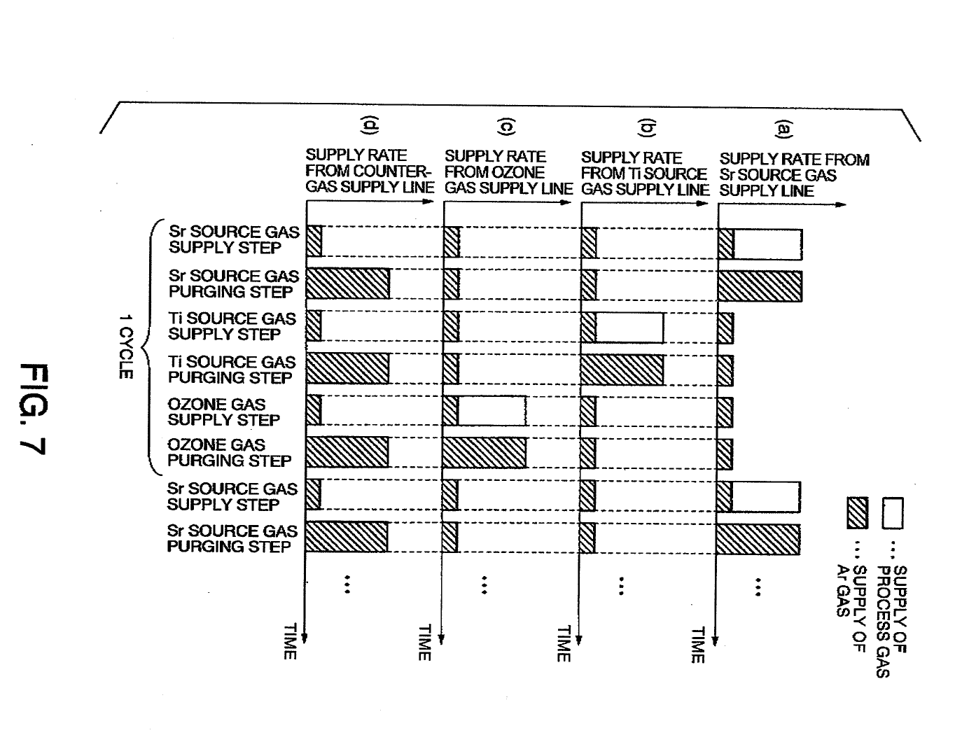

When STO deposition uses the ALD process, the deposition is executed in accordance with a gas supply step, which is shown in FIGS. 7(a) to 7(d). Columns with a white background in FIGS. 7(a) to 7(c) denote the supply rates of the process gases (Sr source gas, Ti source gas, and ozone gas) from the gas supply lines 71 to 73. Hatched columns in FIGS. 7(a) to 7(d) denote supply rates of the Ar gas from the gas supply lines 71 to 74.

As shown in FIG. 7(a), in the Sr source gas supply step, the Sr source gas and the Ar gas are supplied from the Sr source gas supply line 71 through the gas introduction route 35 to the gas-conducting space 32. The Ar gas from the gas supply line 74 is likewise supplied in the Sr source gas supply step. In this step, as shown in FIGS. 7(b) and 7(c), in order to prevent the Sr source gas from flowing into each gas introduction port used for the film deposition, a small amount of Ar gas is also supplied from the Ti source gas supply line 72 and the ozone gas supply line 73 to the gas introduction route 35. Additionally, for the same purpose as above, the Ar gas is supplied from the Ar gas introduction port not directly used for the deposition, in the Ti source gas supply step and the ozone gas supply step.

The Sr source gas and Ar gas that have thus been supplied to the gas introduction route 35 each flow downstream along the gas introduction route 35 while, as described above, forming a vortex flow that rotates in the circumferential direction of the device body 31, and then flow into the gas-conducting space 32. After this, as indicated by arrows in FIG. 2, the gases are dispersed into the gas flow channels 51 to 57 partitioned by the partitioning members 41 to 46, then the gases are supplied to the surface of the wafer W, and molecules that constitute the Sr source gas become adsorbed onto the wafer W. Excesses of the Sr source gas and Ar gas are released through the exhaust line 23 and removed from the processing space S.

After a required time has elapsed and an adsorption layer of the Sr source gas has been formed on the wafer W, supply of each gas is stopped and the Ar gas is supplied as a purging gas from the Sr source gas supply line 71 and the gas supply line 74 to purge away any residues of the Sr source gas from the process chamber 21 and the gas supply unit 3. This purging step is called the Sr source gas purging step. In this step, as shown in FIGS. 7(b) and 7(c), in order to prevent the Sr source gas from flowing into each gas introduction port and reacting with other process gases, a small amount of Ar gas is also supplied from the Ti source gas supply line 72 and the ozone gas supply line 73 to the gas introduction route 35, as in the Sr source gas supply step. Additionally, for the same purpose as above, the Ar gas is supplied from the Ar gas introduction port in the purging steps that follow the Ti source gas supply step and the ozone gas supply step.

After the Ar gas has been supplied for a predetermined time and the Sr source gas has been purged away, the Ti source gas and Ar gas from the Ti source gas supply line 72, and the Ar gas from the gas supply line 74 are supplied to the gas introduction route 35, as shown in FIGS. 7(b) and 7(d). This process step is called the Ti source gas supply step. As with the Sr source gas and Ar gas in the Sr source gas supply step, the Ti source gas and Ar gas that have thus been supplied to the gas introduction route 35 each flow through the gas-conducting space 32 and are supplied to the wafer W. Molecules that constitute the Ti source gas then become adsorbed onto the wafer W. Excesses of the Ti source gas and Ar gas are removed from the processing chamber 21 through the exhaust line 23.

After a required time has elapsed and an adsorption layer of the Ti source gas has been formed on the wafer W, supply of each gas is stopped and then as shown in FIGS. 7(b) and 7(d), the Ar gas is supplied as a purging gas from the Ti source gas supply line 72 and the counter gas supply line 74 to purge away any residues of the Ti source gas from the process chamber 21 and the gas supply unit 3. This purging step is called the Ti source gas purging step.

After the Ar gas has been supplied for a predetermined time and the Ti source gas has been purged away, the ozone gas and Ar gas from the ozone gas supply line 73, and the Ar gas from the gas supply line 74 are supplied to the gas introduction route 35, as shown in FIGS. 7(c) and 7(d). This process step is called the ozone gas supply step. As with the Sr source gas and Ar gas in the Sr source gas supply step, the ozone gas and Ar gas that have thus been supplied to the gas introduction route 35 each flow through the gas-conducting space 32 and are supplied to the wafer W. The ozone gas forms a molecular layer of STO by reacting with those molecules of the source gases which are already adsorbed to the surface of the wafer W by heat from the heaters 22a within the mounting table 22.

After a required time has elapsed, supply of the ozone gas and Ar gas is stopped and then as shown in FIGS. 7(c) and 7(d), the Ar gas is supplied as a purging gas from the ozone gas supply line 73 and the counter gas supply line 74 to purge away any residues of the ozone gas from the process chamber 21 and the gas supply unit 3. This purging step is called the ozone gas purging step.

As shown in FIGS. 7(a) to 7(d), if the six steps described above are taken as one cycle, the molecular layer of STO is multilayered by repeating the cycle a predetermined number of times, for example, 100 times, to complete the deposition of the STO film having required thickness. Upon completion of the deposition, each source of gas supply is deactivated and after the internal pressure of the process chamber 21 has been returned to the level existing before vacuum evacuation, the wafer W is unloaded via the external transport mechanism along a route inverse to that of loading. The deposition sequence is thus completed.

In the deposition apparatus 2 described above, each gas is introduced from the gas introduction ports 61a to 63a, 61b to 63b, and 64 connected to the gas supply lines 71 to 74, into the diametrally reduced end 32a of the nearly conical gas-conducting space 32. The gas next flows through the gas-conducting space 32 along the partitioning members 41 to 46 provided concentrically. The partitioning members 41 to 46 are increased in downstream progressive enlarging rate the farther outward they are disposed. After thus being supplied to the gas-conducting space 32, the gas is supplied to the wafer W, such that conductance of the gas in the flow channels (i.e., an easiness level of flow of the gas) to the wafer W is increased. In such ALD process as described above, therefore, the process gas containing either the Sr source gas, the Ti source gas, or the ozone gas, can be rapidly supplied to the wafer W after being supplied to the gas-conducting space 32. The purging process for replacement with the Ar gas after each source gas been supplied can also be performed rapidly. This improves throughput.

The gas supply unit 3 is easy to manufacture, since the device has a structure that, unlike that of the foregoing gas showerhead, requires no precise, complex working. The kinds of materials to be used to form the device body 31 and/or the partitioning members 41 to 46 can include, for example, aluminum, a mixture of silicon carbide (SiC) and aluminum, or ceramics. The gas supply unit 3, therefore, has an advantage of great flexibility in selection of the kinds of materials useable to manufacture the unit. Additionally, selection of an easily workable material such as aluminum allows easy addition or deletion of gas introduction ports, depending on the number of kinds of gases required for processing.

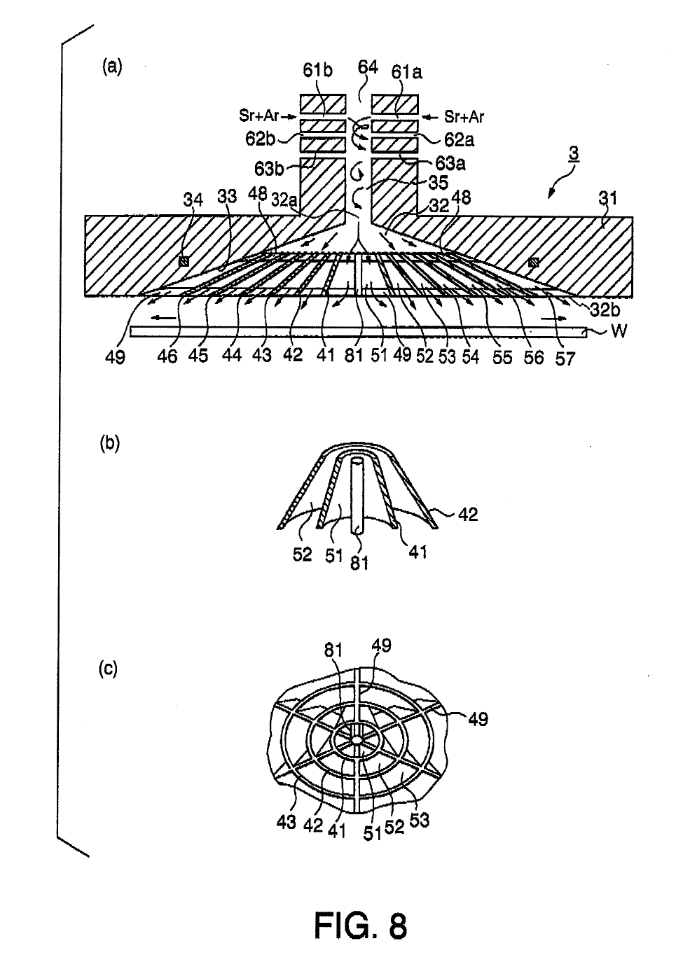

A first modification of the gas supply unit 3 is described below referring to FIG. 8(a). In the following description of the first modification, sections formed to have substantially the same construction as that of the elements of the above embodiment are assigned the same reference numbers or symbols as used in the embodiment, and description of these sections is omitted.

The modification shown in FIG. 8(a) includes a rod-like airflow control member 81 internally to the partitioning member 41. The airflow control member 81 keeps any gas from flowing into a radial central region of the gas-conducting space 32. Providing the airflow control member 81 at the radial central side of the nearly conical gas-conducting space 32 that facilitates the flow of the gas is effective for supplying the gas to the entire surface of the wafer W uniformly and enhancing in-plane processing uniformity of the wafer.

FIG. 8(b) is a perspective view of the airflow control member 81, and FIG. 8(c) is a perspective view of the airflow control member 81 and periphery near the bottom of the gas supply unit 3. The supports 48 and 49, although omitted in FIG. 8(b) for the sake of convenience in illustration, extend towards the inside of the partitioning member 41 and support the airflow control member 81.

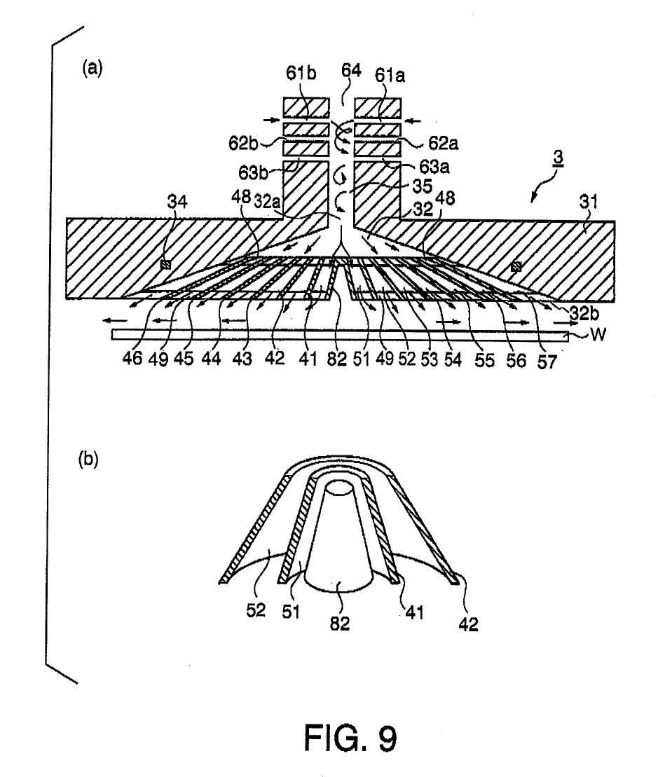

FIG. 9(a) shows a second modification of the gas supply unit 3. In the second modification, a tubular partitioning member 82 with a blocked upper end, serving as an airflow control member, is provided internally to the partitioning member 41. This layout of the partitioning member 82 prevents gases from flowing into the radial central region of the gas-conducting space 32, as described above, and is thus effective for supplying the gas to the entire surface of the wafer W uniformly and enhancing the in-plane processing uniformity of the wafer. FIG. 9(b) is a perspective view of the partitioning member 82. The partitioning member 82, as with the airflow control member 81, is supported by the supports 48 and 49 that extend towards the radial inside of the gas-conducting space 32. The partitioning member 82, however, is omitted in FIG. 9(b) for the sake of convenience in illustration.

In the gas supply unit 3 shown in FIGS. 8(a) and 9(a), for example, a spacing as well as inclinations of the partitioning members 41 to 46 and the shapes of the airflow control member 81 and partitioning member 82 may be adjustable to enhance the in-plane processing uniformity of the wafer W as well as to provide the airflow control member 81 or the partitioning member 82. The adjustment preferably increases the gas conductance of the gas flow channels 51 to 57 as they go outward from the radial inside of the device body 31. In other words, the gas flow channels 57, 56, 55, 54, 53, 52, and 51 are preferably constructed and arranged to have higher gas conductance in that order. This layout leads to uniform in-plane supply of the gas to the wafer W, and hence, uniform in-plane film deposition thereon.

In the first embodiment, as described above, the conductance of the gas in the gas flow channels 51 to 57 can likewise be increased as they go radially outward, by adjusting the inclinations and spacing of the partitioning members 41 to 46, thereby to ensure uniform supply of the gas. In the first embodiment and each modification thereof, the gas may alternatively be supplied uniformly by changing the number of partitioning members to be arranged in the gas-conducting space 32.

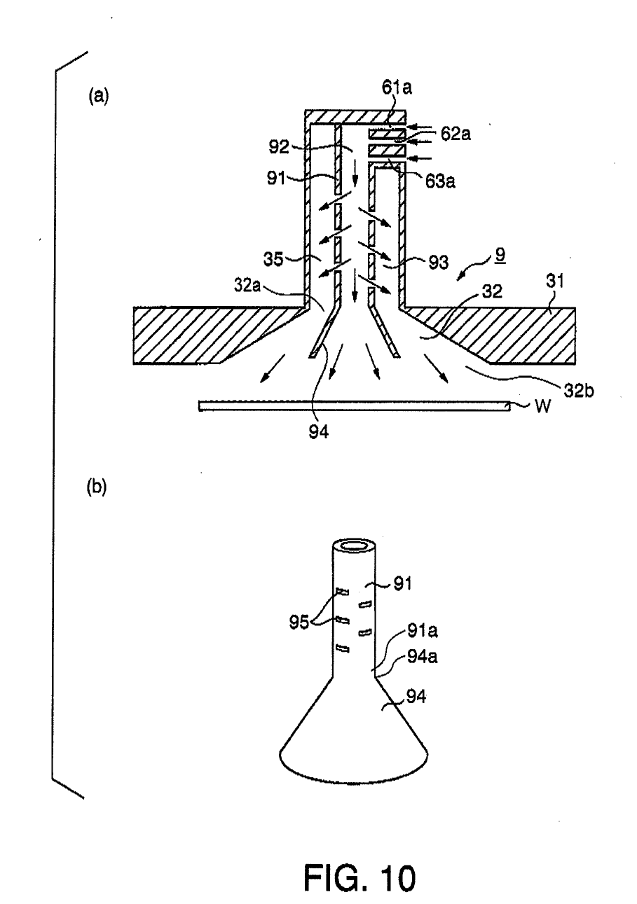

FIG. 10(a) shows a gas supply unit 9 that is a third modification of the gas supply unit. In a gas introduction route 35 of the gas supply unit 9, a separating member 91 is provided to separate the gas introduction route 35 radially into an inner region 92 and an outer region 93. A partitioning member 94 constructed similarly to the partitioning member 41 is provided in the gas-conducting space 32. As shown in FIG. 10(b), the separating member 91 is connected at its lower end 91a to an upper end 94a of the partitioning member 94.

Gas introduction ports 61a to 63a are constructed to supply gases to the inner region 92, and a plurality of orifices 95 for diffusing towards the outer region 93 the gases supplied to the inner region 92 are provided in a sidewall of the separating member 91. The gases from the gas introduction ports 61a to 63a, therefore, are first supplied to the inner region 92 and then diffused therefrom through the plurality of orifices 95, towards the outer region 93. In the thus-constructed gas supply unit, substantially the same effects as in an example of the first embodiment can be obtained since the unit, unlike a gas showerhead, does not require passing the gases through a complex, fine-structured flow channel.

### Second Embodiment

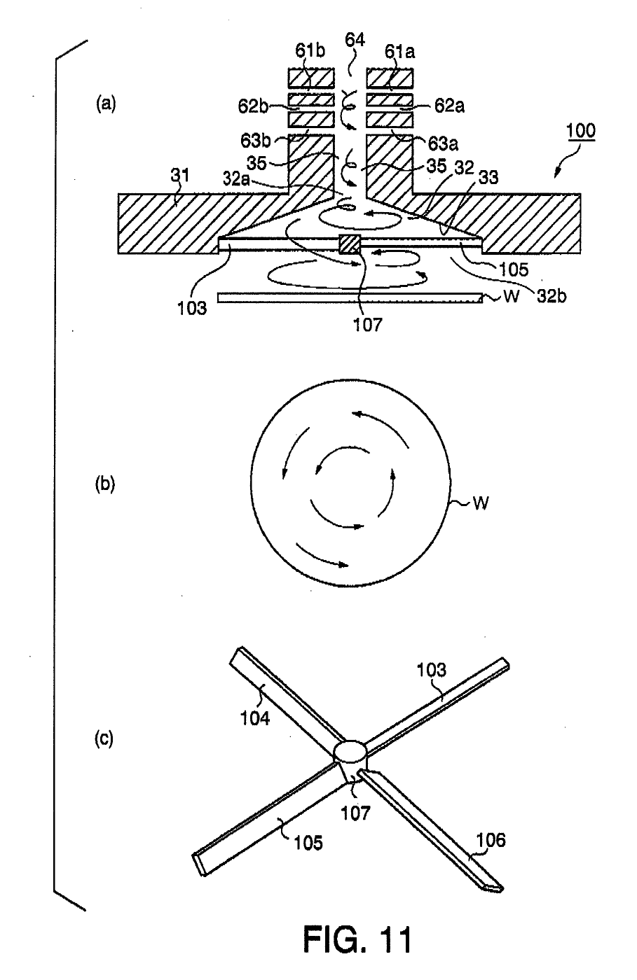

A second embodiment of the gas supply device constituting the gas supply unit of the above-described film deposition apparatus 2 is described below referring to FIG. 11(a).

Although constructed similarly to the gas supply unit 3, the gas supply unit 100 shown in FIG. 11(a) has none of the above-described partitioning members 41 to 46 in the gas-conducting space 32. Instead, the gas supply unit 100 has plate-like partitioning members 103 to 106 so as to partition the gas-conducting space 32 in a circumferential direction thereof. The partitioning members 103 to 106 each extend radially from a central portion of the gas-conducting space 32, towards an inner circumferential surface 33 of the device body 31.

For example, each partitioning member 103 to 106 is supported at one end thereof by the inner circumferential surface 33, and at the other end by a support 107 provided centrally in the radial direction. FIG. 11(c) is a perspective view of the partitioning members 103 to 106 and the support 107.

As denoted by arrows in FIG. 11(a), when gases are introduced from gas introduction ports 61a to 63a and 61b to 63b, the gases each flow downward towards a diametrally enlarged end 32b of the gas-conducting space 32 while forming a vortex flow that rotates in a circumferential direction of the device body 31 as is the case with the first embodiment. The gas is guided along the partitioning members 103 to 106 and the vortex flow is delivered from the diametrally enlarged end 32b to the wafer W. FIG. 11(b) shows an upper surface of the wafer W existing when the gas is thus supplied thereto, and the flow of the gas is denoted by arrows.

Even in the configuration of the second embodiment, there is no need to pass the gas through a complex, fine-structured flow channel compared with that of a gas showerhead, so that decreases in the conductance of the gas in the gas-conducting space 32 can be suppressed and substantially the same effects as those of the first embodiment can be obtained.

In addition, as described above, the partitioning members 103 to 106 are preferably constructed so that the gas forming the vortex flow will be delivered from the diametrally enlarged end 32b of the gas-conducting space 32 to the wafer W, thereby to implement highly uniform supply of the gas to the entire wafer W. In order to form the vortex flow, the partitioning members 103 to 106 are preferably supported in an inclined state with respective horizontal axes as a center. Angles of each partitioning member 103 to 106 in a direction of the horizontal axis in this case are set appropriately.

Furthermore, while the partitioning members 103 to 106 are provided at the diametrally enlarged end 32b of the gas-conducting space 32 in the present example, the members may be formed to range from the diametrally enlarged end 32b to the diametrally reduced end 32a. Moreover, the number of partitioning members 103 to 106 is not limited to four, and is set appropriately so that the gas is supplied to the wafer W uniformly.

### Third Embodiment

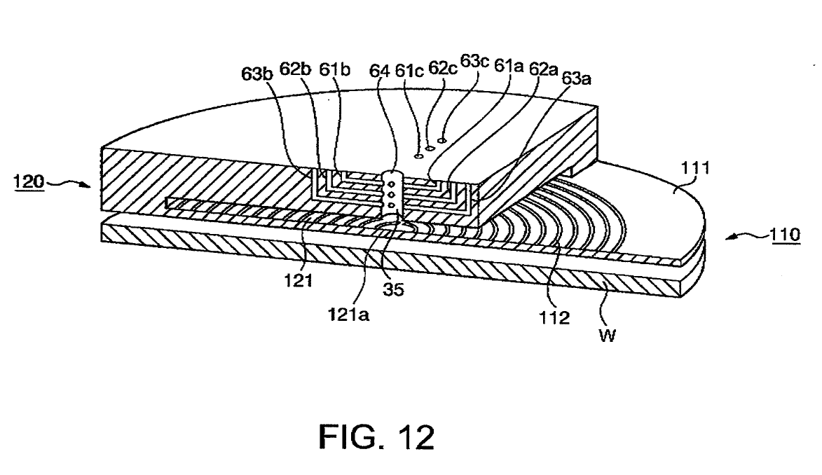

A third embodiment of the gas supply device constituting the gas supply unit of the above-described film deposition apparatus 2 is described below referring to FIG. 12, a sectional perspective view of the present embodiment. The description focuses primarily upon differences from the gas supply unit 3.

The gas supply unit 110 shown in FIG. 12 has its body 120 constructed into a flat, circular shape. In addition, a disc-shaped gas-conducting space 121 instead of the gas-conducting space 32 with a diametrally enlarged lower end is formed in the body 120. The gas-conducting space 121 includes no partitioning members 41 to 46, and has a plate-shaped member 111 at the diametrally enlarged lower end 121a of the gas-conducting space 121.

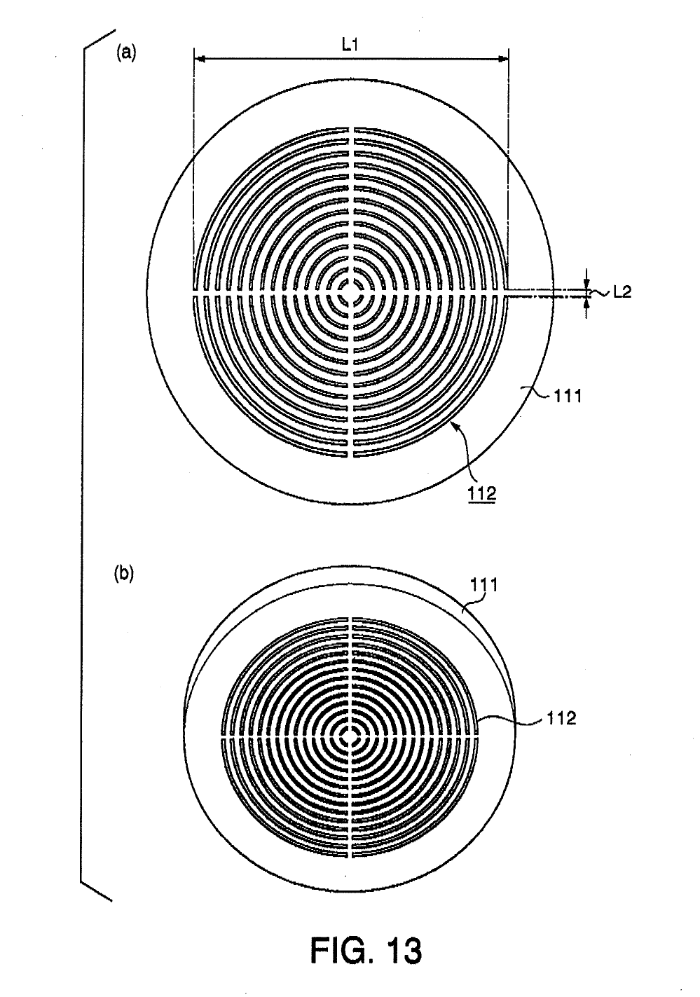

Slits 112 each circumferentially divided into four segments are concentrically opened in the plate-shaped member 111. FIG. 13(a) is a bottom view of the plate-shaped member 111, and FIG. 13(b) is a perspective view of the plate-shaped member 111 as viewed from the underside of the gas supply unit 110. In the present example, 14 slits 112 heading from a central portion of the plate-shaped member 111 towards an outer edge thereof are opened.

Two innermost slits 112 are 2 mm wide, seven slits 112 external to the innermost ones are 3 mm wide, three slits 112 further external thereto are 4 mm wide, and two slits 112 further external to the 4-mm wide slits, that is, closest to the outer edge of the member 111, are 5 mm wide. The 14 slits 112 are thus constructed to be wider as they head for/towards the outer edge of the plate-shaped member 111, and no opening is formed centrally therein. This, as in the modifications of the first embodiment, enhances gas conductance of a radial outer edge of the gas supply unit 110, supplies gases to the entire wafer W uniformly, and improves the in-plane processing uniformity of the wafer W.

Referring to FIG. 13(a), a circle forming an outer edge of the outermost slit 112 in the plate-shaped member 111 has a diameter L1 of 3.00 mm, for example. A distance L2 between the slits 112 circumferentially adjacent to each other is 7 mm, for example.

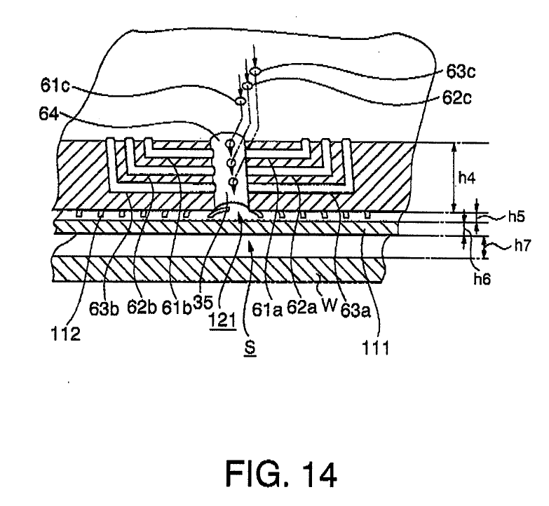

FIG. 14 shows a structural example of a gas introduction route 35 and its periphery. In this example, in order that as in other embodiments, a vortex flow is formed in the gas introduction route 35, gas introduction ports for introducing a strontium (Sr) gas, a titanium (Ti) gas, and an ozone (O₃) gas, are provided in four directions. Since FIG. 14 is a sectional view of the corresponding structure, only three of the four directions in which the gas introduction ports exist are shown in the figure. The gas introduction ports 61c, 62c, and 63c in FIG. 14 are formed as Sr gas, Ti gas, and O₃ gas introduction ports, respectively, as with the gas introduction ports 61a, 62a, and 63a. The remaining gas introduction port not shown is provided so as to face the gas introduction ports 61c, 62c, and 63c. The gas introduction ports for introducing the Sr gas, the Ti gas, and the O₃ gas, have a diameter of 4 mm, for example, and the gas introduction port 64 for introducing an Ar gas has a diameter of 12 mm, for example.

Distance h4 from an upper surface of the body 120 to that of the gas-conducting space 121 is 30 mm, for example; height of the gas-conducting space 121, shown as h5, is 5 mm, for example; thickness h6 of the plate-shaped member 111 is 5 mm, for example; and distance h7 from the surface of the wafer W to a lower surface of the plate-shaped member 111 is 10 mm, for example.

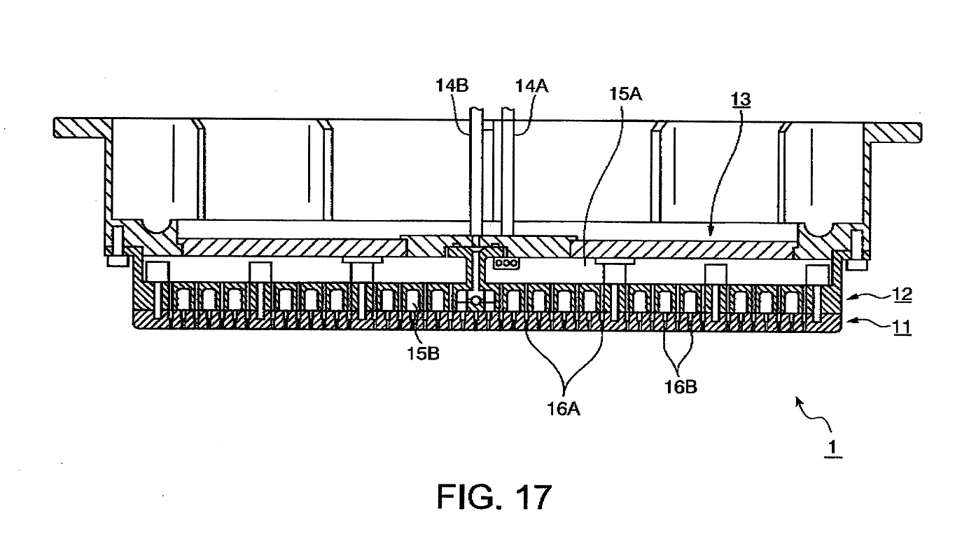

In the gas supply unit 110 of the third embodiment, decreases in the conductance of the gases in the gas-conducting space 121 are also suppressed since there is no need to pass the gases through complex, fine-structured flow channels compared with those of the conventional gas showerhead shown in FIG. 17. Substantially the same effects as those of the first embodiment can be obtained.

While examples of applying the gas supply device of the present invention to a film deposition apparatus have been shown and described in the first, second, and third embodiments, the gas supply device can also be applied to plasma-etching apparatuses adapted to supply a gas to a substrate, then transform the gas into plasma, and etch the substrate. In addition, the application of the gas supply device is not limited to the type of film deposition apparatus that performs the ALD process to intermittently supply different process gases to the substrate at the required cycles, as described above, and the gas supply unit is further applicable to a CVD apparatus that non-intermittently supplies process gases and continuously performs film deposition. In addition, although a semiconductor wafer has been described as an example of a substrate, the applicable kind of substrate is not limited to semiconductor wafers and the present invention is likewise applicable to glass substrates, LCD substrates, ceramic substrates, and the like.

### (Evaluation Tests 1)

In order to confirm the effectiveness of the gas supply unit 3 in the first embodiment, the sequence of supplying gases from the gas introduction ports 61a to 63a, 61b to 63b, 64 of the gas supply unit 3 to the gas-conducting space 32 was simulated using a computer to examine concentration distributions of the gases in the gas-conducting space 32 and at the surface of the wafer W, with an elapse of time from gas introduction. Simulation conditions and results are described below. A mixture of a C₇H₈ gas and an Ar gas, instead of a mixture of the Sr gas and Ar gas used in the embodiment, is supplied from the gas introduction ports 61a and 61b. A supply rate of the gas mixture from the gas introduction ports 61a to 63a and 61b to 63b is 250 mL/min (sccm), and a supply rate from the gas introduction port 64 is 500 mL/min (sccm). A fraction of the C₇H₈ gas supplied from each of the gas introduction ports 61a and 61b is 27%, and a fraction of the Ar gas supplied from each of the gas introduction ports 61a and 61b is 72%. A temperature is set to be 230° C. at the surface of the wafer W and in the processing space S surrounding the wafer. An internal pressure of the processing space S is set to be 45 Pa after the supplied gas mixture has been discharged radially from a central region of the wafer W, along an outer surface thereof.

Simulations on supplying gases from each gas introduction port in accordance with the Sr source gas supply step described in the above embodiment were performed to examine distributions of the C₇H₈ gas supplied instead of the Sr gas. Simulation results are described below. After 0.05 second from gas introduction, the C₇H₈ gas is dispersed in the gas-conducting space 32 and over the entire surface of the wafer W, and after 0.1 second, a C₇H₈ gas concentration of 7.5% in the gas-conducting space 32 and over the entire wafer surface is detected in a certain very small region only. A concentration of 9% is detected in all other regions, so the gas concentration as a whole is nearly uniform.

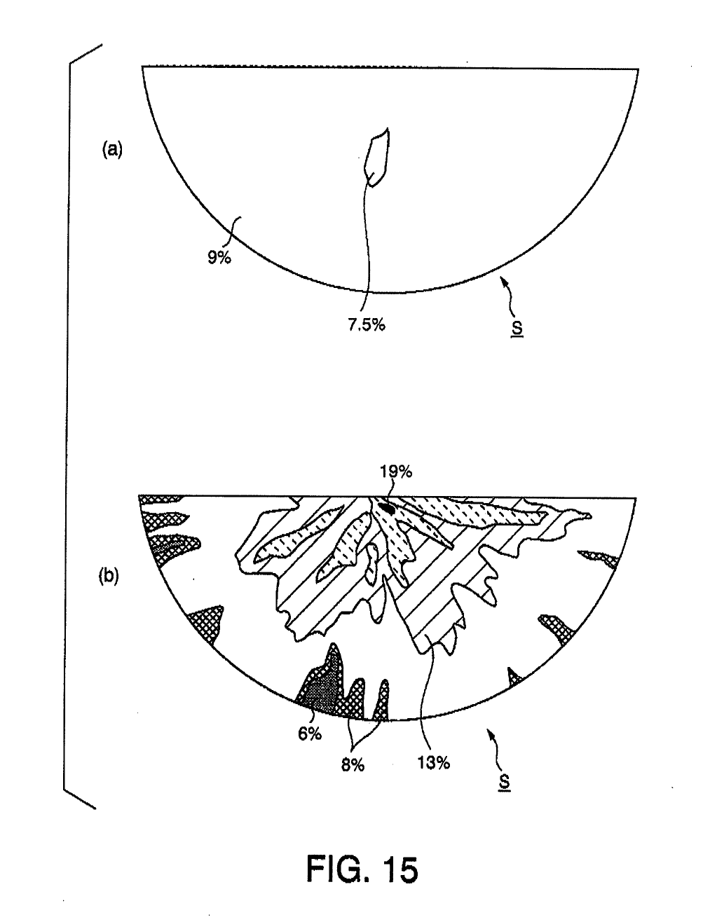

The above was followed by simulation of C₇H₈ gas purging based on the Sr source gas purging step described in the embodiment. After 0.15 second from introduction of the Ar gas for purging, a C₇H₈ gas concentration of nearly 0% in the gas-conducting space 32 and over the entire surface of the wafer W is detected to complete the purging. FIG. 15(a) shows the simulation results relating to the concentration distribution obtained in the processing space S after 0.1 second from supply of the C₇H₈ gas, the gas concentration distribution in the processing space S being plotted in segmented form on an isoconcentration map in the figure. As shown therein, the nearly uniform C₇H₈ gas distribution is obtained. Actual simulation results are output on a color screen so that a concentration distribution is displayed with gradations in computer graphics. The concentration distribution diagrams in FIGS. 15(a) and 15(b), however, are shown in simplified form for the sake of convenience in graphical representation. The concentration distributions in FIGS. 15(a) and 15(b), therefore, are not actually discontinuous, and these figures indicate that abrupt gradients in concentration are present between the segmented regions on the isoconcentration map.

Following the above, simulations on the conventional gas showerhead were conducted using the Sr source gas supply step and the Sr source gas purging step. The simulation tests here, however, used the C₇H₈ gas instead of the Sr gas, as with the simulation of the gas supply unit 3. Differences in concentration after an elapse of 0.1 second from supply of the gas in the source gas supply step are significant, with C₇H₈ gas concentrations of 19% at the central region of the wafer surface and 8% at the wafer outer edge. In FIG. 15(b), these simulation results on the gas concentration distribution are represented in segmented form on an isoconcentration map, as in FIG. 15(a), and sections in the processing space S that indicate a predetermined concentration are marked with dots, lines, or the like, for the sake of convenience in illustration. Dark-masked regions denote the C₇H₈ gas concentration of 19%, and regions hatched with unidirectional solid lines denote a C₇H₈ gas concentration of 13%. Cross-hatched regions denote the C₇H₈ gas concentration of 8%, and dotted regions denote a C₇H₈ gas concentration of 6%. Regions having discontinuous short lines denote C₇H₈ gas concentrations lower than 19%, but higher than 13%. Other regions without dots or lines denote C₇H₈ gas concentrations lower than 13%, but higher than 8%. The simulation results obtained after an elapse of 1.0 second from gas introduction also indicate concentration differences similar to the above. In the Sr source purging step, sections with a high C₇H₈ gas concentration were also detected in the showerhead after 1.0 second from gas introduction.

These simulation results indicate that compared with the conventional gas showerhead, the gas supply unit 3 of the present invention can supply gases to the surface of the wafer W very uniformly and purge the gases rapidly. The term % in these evaluation tests signifies a volume-percent concentration.

### (Evaluation Tests 2)

Similarly to evaluation tests 1, the ozone gas supply step in the gas supply unit 3 was simulated to examine concentration distributions of the ozone gas in the gas-conducting space 32 and at the surface of the wafer W. Simulation test results are described below. The concentration distributions of the ozone gas in the gas-conducting space 32 and at the wafer surface, after 0.05 second from gas introduction, are nearly uniform. The time required until the nearly uniform concentration distributions have been obtained in bath sections is short enough for the apparatus to conduct the ALD process, so that the gas supply unit 3 is considered to be effective in the ALD process.

### (Evaluation Tests 3)

Following the above, simulations similar to those of evaluation tests 1 were performed to examine distributions of C₇H₈ gas concentrations by supplying gases from each gas introduction port in accordance with the Sr source gas supply step and the Sr source gas purging step. Data was set for no Ar gas to be supplied as a counter gas from the gas introduction port 64. Simulation results are described below. In the Sr source gas supply step, the C₇H₈ gas concentrations in the gas-conducting space 32 and at the surface of the wafer W, after 0.1 second from gas introduction, are nearly uniform, with the highest concentration being 11% and the lowest one being 10%. Regions of the 10% concentration account for a proportion greater than that accounted for by the regions of the lowest concentration in evaluation tests 1. In the ensuing Sr source gas purging step, after 0.15 second from gas introduction, the highest of all concentrations in the gas-conducting space 32 and at the surface of the wafer W is 0.01% and the lowest concentration is 0.001%. As described in evaluation tests 1, purging is completed after 0.15 second from Ar gas introduction from the gas introduction port 64, so the results of evaluation tests 1 as well as of evaluation tests 3 indicate that supplying the counter gas from the gas introduction port 64 is preferable for uniform wafer in-plane gas supply and for rapid purging.

### (Evaluation Tests 4)

After the above simulation tests, a gas supply unit 3 without the partitioning members 41 to 46 was set and simulations similar to those of evaluation tests 1 were performed to examine distributions of C₇H₈ gas concentrations by supplying gases from each gas introduction port in accordance with the Sr source gas supply step and the Sr source gas purging step. Simulation test results are described below. In the Sr source gas supply step, distributions of CH₇H₈ gas concentrations are similar to those of evaluation tests 1. In the Sr source gas purging step, however, the concentration of the C₇H₈ gas at the outer edge of the wafer W after 0.15 second from supply of the purging gas is 0.02% and the concentration of the C₇H₈ gas at the central region of the wafer W is 0.001%, the difference between the two concentrations being significant in comparison with the results of evaluation tests 1. These results indicate that the partitioning members 41 to 46 have a function that replaces the gases uniformly.

### (Evaluation Tests 5)

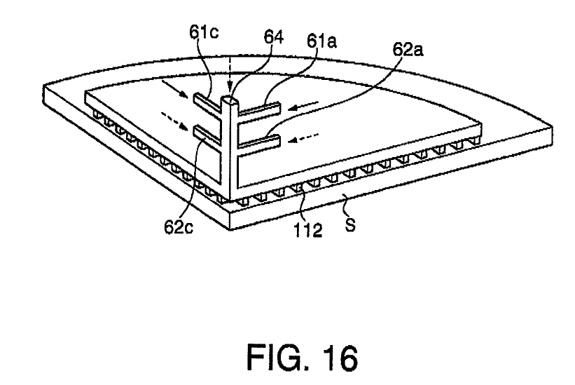

After the above simulation tests, a radially four-forked flow channel model in FIG. 16 was set in the gas supply unit 110 and the sequence of supplying gases from each gas introduction port in accordance with the Sr source gas supply step and the Sr source gas purging step was simulated in a manner similar to that of evaluation tests 1. Data was set for a mixture of a C₇H₈ gas and an Ar gas to be supplied at a rate of 500 mL/min (sccm) from the gas introduction ports 61a and 61c. A flow rate of 0.1 g/min was set for the toluene contained in the gas mixture, and a temperature of 200° C. was set for the surface of the wafer W and the processing space surrounding the wafer. Data was further set for the Ar gas to be supplied at a flow rate of 500 mL/min (sccm) from the gas introduction port 64, and for the Ar gas to be supplied at a total flow rate of 500 mL/min (sccm) from the gas introduction ports 62a and 62c. In the simulation tests, no flow rate was set for other gas introduction ports. A distribution of the toluene gas in the processing space S was examined under these conditions.

Simulation results are described below. After 0.1 second from gas introduction, the toluene gas is distributed in the entire processing space S and the concentration is 4%, which is uniform in the entire processing space S. Comparisons between these results and the simulation results of evaluation tests 1 on the structure of the conventional showerhead indicate that the gas supply unit 110 can supply gases to the surface of the wafer W very uniformly and at high speed.

What is claimed is:

1. A gas supply device disposed oppositely to a substrate in a process chamber and adapted to supply process gases to the substrate so as to process the substrate, the device comprising:
a device body having a gas-conducting space therein, the gas-conducting space having a diametrally reduced end and a diametrally enlarged end and being formed into a substantially conical shape to thereby conduct the gases from the diametrally reduced end through the gas-conducting space to the diametrally enlarged end;
gas introduction ports provided near the diametrally reduced end of the gas-conducting space in the device body to introduce the gases into the gas-conducting space; and
a plurality of partitioning members provided in the gas-conducting space of the device body to partition the gas-conducting space concentrically;
wherein the partitioning members arranged adjacently to each other at a radially outer side of the gas-conducting space are greater than those of a radially inner side in dimensionally diverging rate per partitioning member.

2. The gas supply device according to claim 1, wherein:
a gas introduction route is formed at an upstream side of the gas-conducting space in the device body, the gas introduction route that extends in an axial direction of the gas-conducting space; and
the gas introduction ports are provided at an upstream side of the gas introduction route.

3. The gas supply device according to claim 1, wherein the partitioning members are each supported by support members that extend from an inner circumferential surface of the device body, towards a radially inward side of the gas-conducting space.

4. The gas supply device according to claim 1, wherein the partitioning members partition the gas-conducting space into a plurality of flow channels, the flow channels each being formed so that radially inner flow channels have lower gas conductance than radially outer ones.

5. The gas supply device according to claim 4, further comprising:
an airflow control member disposed in a radially central region of the gas-conducting space to prevent the gases from flowing into the central region.

6. The gas supply device according to claim 2, further comprising:
a divider member provided in the gas introduction route to divide the gas introduction route into a radially inner region thereof and a radially outer region thereof, the divider member including a plurality of orifices to diffuse the gases supplied to the inner region towards the outer region;
wherein the gases from the gas introduction ports are supplied to the inner region.

7. The gas supply device according to claim 6, wherein the divider member is connected to upstream ends of the partitioning members.

8. A gas supply device disposed oppositely to a substrate in a process chamber and adapted to supply gases to the substrate so as to process the substrate, the device comprising:
a device body having a gas-conducting space therein, the gas-conducting space having a diametrally reduced end and a diametrally enlarged end and being formed into a substantially conical shape to thereby conduct the gases from the diametrally reduced end through the gas-conducting space to the diametrally enlarged end;
gas introduction ports provided near the diametrally reduced end of the gas-conducting space in the device body to introduce the gases into the gas-conducting space; and
a plurality of partitioning members provided in the gas-conducting space of the device body to partition the gas-conducting space in a circumferential direction thereof.

9. The gas supply device according to claim 8, wherein:
a gas introduction route is formed at an upstream side of the gas-conducting space in the device body, the gas introduction route that extends in an axial direction of the gas-conducting space; and
the gas introduction ports are provided at an upstream side of the gas introduction route.

10. The gas supply device according to claim 8, wherein the plurality of partitioning members are each constructed so that the gases supplied from the diametrally enlarged end of the gas-conducting space will flow while forming a vortex flow that rotates in the circumferential direction of the device body.

11. The gas supply device according to claim 8, wherein the partitioning members extend radially from the central region of the gas-conducting space.

12. The gas supply device according to claim 8, wherein the partitioning members are provided to range from the diametrally reduced end to the diametrally enlarged end, in the gas-conducting space.

13. A gas supply device disposed oppositely to a substrate in a process chamber and adapted to supply gases to the substrate so as to process the substrate, the device comprising:
a device body with a gas-conducting space for conducting the gases therethrough;
gas introduction ports provided near an upstream end of the gas-conducting space in the device body to introduce the gases into the gas-conducting space; and
a plate-like member provided near a downstream end of the gas-conducting space in the device body, the plate-like member having a plurality of concentrically opened slits for supplying the gases to the substrate through the gas-conducting space.

14. The gas supply device according to claim 13, wherein:
a gas introduction route is formed at an upstream side of the gas-conducting space in the device body, the gas introduction route that extends in an axial direction of the gas-conducting space; and
the gas introduction ports are provided at an upstream side of the gas introduction route.

15. The gas supply device according to claim 13, wherein the slits are formed to increase in interslit width as they go radially from a central portion of the plate-like member, towards an outer edge of the member.

16. The gas supply device according to claim 1, further comprising temperature control means in the device body.

17. A processing apparatus comprising:
a mounting table for mounting a substrate thereon;
a process chamber with the mounting table provided therein;
a gas supply device provided oppositely to the mounting table, for supplying plural kinds of process gases to the process chamber interior to process the substrate; and
means for evacuating the process chamber interior;
wherein the gas supply device includes
a device body having a gas-conducting space therein, the gas-conducting space having a diametrally reduced end and a diametrally enlarged end and being formed into a substantially conical shape to thereby conduct the gases from the diametrally reduced end through the gas-conducting space to the diametrally enlarged end;
gas introduction ports provided near the diametrally reduced end of the gas-conducting space in the device body to introduce the gases into the gas-conducting space, and
a plurality of partitioning members provided in the gas-conducting space of the device body to partition the gas-conducting space concentrically; and
the partitioning members arranged adjacently to each other at a radially outer side of the gas-conducting space are greater than those of a radially inner side in dimensionally diverging rate per partitioning member.

18. The processing apparatus according to claim 17, further comprising:
a plurality of process gas flow channels connected to the gas introduction ports of the gas supply device, the process gas flow channels each being formed to supply any one of the plural kinds of process gases;
a purging gas flow channel connected to any one of the gas introduction ports of the gas supply device, the purging gas flow channel being formed to supply an inert gas for purging; and
a supply gas control device that controls a supply state of the gases in the process gas flow channels and in the purging gas flow channel; and
a control unit that controls the supply gas control device to conduct the step of, in addition to supplying the plural kinds of process gases in order and cyclically, supplying the inert gas between the step of supplying one of the plural kinds of process gases and the step of supplying the other kind of process gas;
wherein layers that include reaction products of the plural kinds of process gases are sequentially stacked on the surface of the substrate to form a thin film thereon.

19. A processing method comprising the steps of;
mounting a substrate on a mounting table provided in a process chamber;
supplying process gases for processing the substrate, from a gas supply device opposed to the mounting table, to the process chamber interior; and
evacuating the process chamber interior;
wherein the gas supply device includes
a device body having a gas-conducting space therein, the gas-conducting space having a diametrally reduced end and a diametrally enlarged end and being formed into a substantially conical shape to thereby conduct the gases from the diametrally reduced end through the gas-conducting space to the diametrally enlarged end,
gas introduction ports provided near the diametrally reduced end of the gas-conducting space in the device body to introduce the gases into the gas-conducting space, and
a plurality of partitioning members provided in the gas-conducting space of the device body to partition the gas-conducting space concentrically; and
the partitioning members arranged adjacently to each other at a radially outer side of the gas-conducting space are greater than those of a radially inner side in dimensionally diverging rate per partitioning member.

20. The processing method according to claim 19, wherein;
the step of supplying the process gases includes the substep of, in addition to supplying the plural kinds of process gases in order and cyclically, supplying an inert gas between the step of supplying one of the plural kinds of process gases and the step of supplying the other kind of process gas; and
layers that include reaction products of the plural kinds of process gases are sequentially stacked on the surface of the substrate to form a thin film thereon.

21. A storage medium having stored therein a computer program that operates on a computer, the storage medium being used in a processing method,
wherein the processing method comprises the steps of:
mounting a substrate on a mounting table provided in a process chamber;
supplying plural kinds of process gases for processing the substrate, from a gas supply device opposed to the mounting table, to the process chamber interior; and
evacuating the process chamber interior;
wherein the gas supply device includes a device body having a gas-conducting space therein, the gas-conducting space having a diametrally reduced end and a diametrally enlarged end and being formed into a substantially conical shape to thereby conduct the gases from the diametrally reduced end through the gas-conducting space to the diametrally enlarged end,
gas introduction ports provided near the diametrally reduced end of the gas-conducting space in the device body to introduce the gases into the gas-conducting space, and
a plurality of partitioning members provided in the gas-conducting space of the device body to partition the gas-conducting space concentrically, and
wherein the partitioning members arranged adjacently to each other at a radially outer side of the gas-conducting space are greater than those of a radially inner side in dimensionally diverging rate per partitioning member.
